(19) United States
(12) Patent Application Publication
(10) Pub. No.: US 2013/0207209 A1
(43) Pub. Date: Aug. 15, 2013

(54) TOP-PINNED MAGNETIC TUNNEL JUNCTION DEVICE WITH PERPENDICULAR MAGNETIZATION

(71) Applicants: Yung-Hung Wang, Hsinchu County (TW); Kuei-Hung Shen, Hsinchu City (TW); Ding-Yeong Wang, Hsinchu County (TW); Shan-Yi Yang, Hsinchu City (TW)

(72) Inventors: Yung-Hung Wang, Hsinchu County (TW); Kuei-Hung Shen, Hsinchu City (TW); Ding-Yeong Wang, Hsinchu County (TW); Shan-Yi Yang, Hsinchu City (TW)

(73) Assignee: INDUSTRIAL TECHNOLOGY RESEARCH INSTITUTE, Hsinchu (TW)

(21) Appl. No.: 13/447,283

(22) Filed: Apr. 16, 2012

(30) Foreign Application Priority Data
Feb. 15, 2012 (TW) 101104902

(51) Int. Cl. H01L 29/82

(52) U.S. Cl. 257/421; 257/E29.323

(57) ABSTRACT

A top-pinned magnetic tunnel junction device with perpendicular magnetization, including a bottom electrode, a non-ferromagnetic spacer, a free layer, a tunneling barrier, a synthetic antiferromagnetic reference layer and a top electrode, is provided. The non-ferromagnetic spacer is located on the bottom electrode. The free layer is located on the non-ferromagnetic spacer. The tunnel insulator is located on the free layer. The synthetic antiferromagnetic reference layer is located on the tunneling barrier. The synthetic antiferromagnetic reference layer includes a top reference layer located on the tunneling barrier, a middle reference layer located on the bottom reference layer and a bottom reference layer located on the tunneling barrier. The magnetization of the top reference layer is larger than that of the bottom reference layer. The top electrode is located on the synthetic antiferromagnetic reference layer.

### CROSS-REFERENCE TO RELATED APPLICATION

This application claims the priority benefit of Taiwan application serial no. 101104902, filed on Feb. 15, 2012. The entirety of the above-mentioned patent application is hereby incorporated by reference herein and made a part of this specification.

### TECHNICAL FIELD

The disclosure relates to a top-pinned magnetic tunnel junction device with perpendicular magnetization.

### BACKGROUND

A magnetic random access memory (MRAM) mainly uses in-plane magnetic anisotropy (IMA) materials as the magnetic layers of the magnetic tunnel junction (MTJ). The most challenging issue to realize, for example, a spin transfer torque MRAM (STT-MRAM) with IMA films is not only to enhance the thermal stability of a device but also to improve the data writing or reading accuracy, while the writing current density (J_{C}) of the device is reduced. This issue will be more serious when the technology node continues to scale down, for example, the STT MRAM entering into 45 nanometer technology node, unless there is a breakthrough in the characteristics of the magnetic material. A p-MTJ device using perpendicular magnetic anisotropy (PMA) materials to replace the in-plane magnetic anisotropy materials is a feasible approach for resolving the above issue. However, the reference layer in a p-MTJ device, unlike in-plane materials, is unable to form a closed magnetic flux through a synthetic antiferromagnetic (SAF) structure. Accordingly, the free layer is affected by the magnetic field leakage from the reference layer, resulting in an asymmetrical magnetic field or current required for magnetization reversal.

MTJ can be differentiated into in-plane magnetization and perpendicular magnetization in view of magnetization direction, and also can be further differentiated into two types of structure: bottom-pinned and top pinned. The bottom pinned type refers to the reference layer being positioned under the tunneling barrier layer, while the free layer is positioned above the tunneling barrier layer. The top pinned type refers to the reference layer being positioned above the tunneling barrier layer, while the free layer is positioned underneath the tunneling barrier layer. In terms of p-MTJ, the top-pinned type structure should provide better characteristics mostly because the free layer PMA characteristics are more easily adjusted by the seed layer. On the other hand, the free layer of the bottom-pinned type has to be grown on a bcc-(001) magnesium oxide (MgO) insulating layer, and a magnesium oxide bottom layer is unfavorable to the structure grown from a PMA material. Another reason that a top-pined structure is preferred is that both the free layer and the tunneling barrier layer comprise a smooth surface, resulting with a more favorable device characteristic. However, since the free layer is only a few nanometer thick, when the device with the top-pinned structure is etched to the bottom electrode during the fabrication process, the materials of the bottom electrode may be re-deposited on the sidewall to form a short-circuit path on the sidewall of the insulating layer, resulting with an ineffective device. Incidentally, the reference layer is grown above the tunneling bather layer; the MgO layer is also not favorable to the PMA characteristics or structure.

### SUMMARY

An exemplary embodiment of the disclosure provides a top-pinned magnetic tunnel junction device with perpendicular magnetization that includes a bottom electrode, a non-ferromagnetic spacer, a free layer, a tunneling barrier layer, a synthetic antiferromagnetic reference layer and a top electrode. The non-ferromagnetic spacer is positioned on the bottom electrode layer. The free layer is configured on the non-ferromagnetic spacer. The tunneling barrier layer is positioned on the free layer. The synthetic antiferromagnetic reference layer is configured on the tunneling barrier layer. The synthetic antiferromagnetic reference layer includes a bottom reference layer, a middle reference layer and a top reference layer. The bottom reference layer is configured on the tunneling barrier layer. The middle reference layer is configured on the bottom reference layer and is a ruthenium layer. The top reference layer is configured on the middle reference layer. The magnetization of the top reference layer is greater than that of the bottom reference layer. The top electrode is configured on the top reference layer of the synthetic antiferromagnetic reference layer with perpendicular magnetization.

An exemplary embodiment of the disclosure provides a top-pinned magnetic tunnel junction device with perpendicular magnetization that includes a bottom electrode, a non-ferromagnetic spacer, a free layer, a tunneling barrier layer, a synthetic antiferromagnetic reference layer and a top electrode. The non-ferromagnetic spacer is located on the bottom electrode. The non-ferromagnetic spacer includes at least a first spacer positioned on the bottom electrode and a second spacer positioned on the first spacer. The free layer is configured on the non-ferromagnetic spacer. The tunneling barrier layer is configured on the free layer. The antiferromagnetic reference layer is located on the tunneling barrier layer. The top electrode is positioned on the synthetic antiferromagnetic reference layer with perpendicular magnetization.

An exemplary embodiment of the disclosure provides a top-pinned magnetic tunnel junction device with perpendicular magnetization that includes a bottom electrode, a non-ferromagnetic spacer, a free layer, a tunneling barrier layer, a synthetic antiferromagnetic reference layer and a top electrode. The non-ferromagnetic spacer is located on the bottom electrode. The non-ferromagnetic spacer includes at least a first spacer positioned on the bottom electrode and a second spacer positioned on the first spacer. The free layer is configured on the non-ferromagnetic spacer. The tunneling barrier layer is positioned on the free layer. The synthetic antiferromagnetic reference layer is located on the tunneling barrier layer. The synthetic antiferromagnetic reference layer includes a bottom reference layer, a middle reference layer and a top reference layer. The bottom reference layer is configured on the tunneling barrier layer. The middle reference layer is configured on the bottom reference layer and is a ruthenium layer. The top reference layer is configured on the middle reference layer. The magnetization of the top reference layer is greater than that of the bottom reference layer. The top electrode is configured on the top reference layer of the synthetic antiferromagnetic reference layer with perpendicular magnetization.

The disclosure and certain merits provided by the application can be better understood by way of the following exemplary embodiments and the accompanying drawings, which are not to be construed as limiting the scope of the disclosure.

### BRIEF DESCRIPTION OF THE DRAWINGS

FIG. 1 is a schematic, cross-sectional view diagram of a top-pinned magnetic tunnel junction device with perpendicular magnetization according to an exemplary embodiment of the disclosure.

FIG. 2A illustrates the hysteresis loops of the free layer reversal in Examples 1 to 4.

FIG. 2B illustrates the relationship between the number of the repeated layers (Co layer/Pt layer) in the top reference layer and the shifting amount of the magnetic field in the free layer.

FIG. 3A illustrates the hysteresis loops of the free layer reversal in Examples 5 to 7.

FIG. 3B illustrates the relationship between the number of the repeated layers (Co layer/Pt layer) in the top reference layer and the shifting amount of the magnetic field in the free layer.

### DETAILED DESCRIPTION OF DISCLOSED EMBODIMENTS

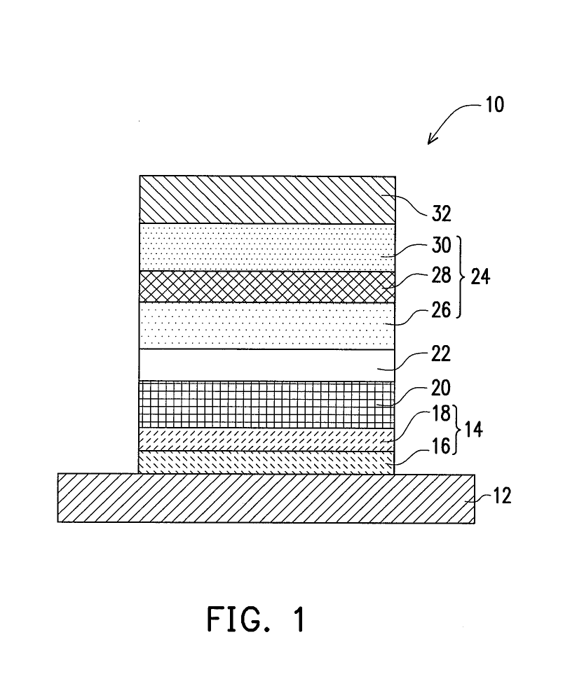

FIG. 1 is a schematic, cross-sectional view diagram of a top-pinned magnetic tunnel junction device with perpendicular magnetization.

An exemplary embodiment of the disclosure provides a top-pinned magnetic tunnel junction device with perpendicular magnetization, in which the redeposit of the bottom electrode materials to the top and bottom of the tunneling barrier layer during an etching to generate a short-circuit path is prevented.

An exemplary embodiment of the disclosure provides a top-pinned magnetic tunnel junction device with perpendicular magnetization, wherein the asymmetrical reversal characteristic of the free layer affected the electric field leakage from the bottom reference layer is mitigated.

Referring to FIG. 1, a top-pinned magnetic tunnel junction device 10 with perpendicular magnetization includes a bottom electrode 12, a non-ferromagnetic spacer 14, a free layer 20, a tunneling barrier layer 22, a synthetic antiferromagnetic reference layer 24 and a top electrode 32.

The material of the bottom electrode 12 includes a metal conductive material, for example Ta (tantalum) or TaN (tantalum nitride). The non-ferromagnetic spacer 14, configured on the bottom electrode 12, serves to increase the distance between the free layer 20 and the bottom electrode 12. Hence, the re-deposit of the bottom electrode 12 materials to the top and bottom of the tunneling barrier layer 22 during the etching process is prevented and the formation a short-circuit path is obviated. The non-ferromagnetic spacer 14 includes at least a first spacer 16 and a second spacer 18. The first spacer 16 is configured on the bottom electrode 12, wherein a material thereof is an amorphous-like or a material with a grain size smaller than 100 nm, for example PtMn (platinum manganese) alloy, copper nitride, nitrogen-doped copper film or N-doped Cu film, which has a smooth surface and a thickness of about 1 to 100 nm. The second spacer 18 is positioned on the first spacer 16, and the second spacer 18 serves to isolate the exchange coupling between the first spacer 16 (for example, PtMn) and the magnetic material of the free layer 20. The material of the second spacer 18 includes the non-ferromagnetic material, such as Ta (tantalum) or Ru (ruthenium). The thickness of the second spacer is about 1 to 10 nm.

The free layer 20 is configured on the non-ferromagnetic spacer 14. The free layer 20 includes one or a plurality of perpendicular magnetic anisotropy materials, such as a CoFeB single layer film, a multi-layer film formed with Co (cobalt) layers and Pt (platinum) layers, a multi-layer film formed with Co (cobalt) layers and Pd (palladium) layers, a multi-layer film formed with Co layers and Ni (nickel) layers, CoPd alloy, FePt alloy, or a combination thereof. In one exemplary embodiment, the free layer 20 includes CoFeB layer and is in direct contact with the tunneling barrier layer 22 to achieve a high tunneling-magneto-resistance ratio. The thickness of the free layer 20 is in the range of, for example, about 0.5 to 10 nm.

The tunneling barrier 22 is configured on the free layer 20. The tunneling barrier layer 22 includes aluminum oxide or magnesium oxide. The thickness of the tunneling barrier layer 22 is in the range of, for example, about 0.5 to 3 nm.

The synthetic antiferromagnetic reference layer 24 is configured above the tunneling barrier layer 22. The synthetic antiferromagnetic reference layer 24 includes a bottom reference layer 26, a middle reference layer 28 and a top reference layer 30. The bottom reference layer 26 is configured on the tunneling barrier layer 22. The middle reference layer 28 is configured on the bottom reference layer 26 and the top reference layer 30 is configured on the middle reference layer 28.

The middle reference layer 28 of the synthetic antiferromagnetic reference layer 24 is a ruthenium layer and has a thickness in a range of about 0.7 to 1 nm, for example. The bottom reference layer 26 and the top reference layer 30 of the synthetic antiferromagnetic reference layer 24 include perpendicular magnetic anisotropy materials. For example, the bottom reference layer 26 and the top reference layer 30 respectively include a CoFeB single layer film, a multi-layer film formed with Co layers and Pt layers, a multi-layer film formed with Co layers and Pd layers, a multi-layer film formed with Co layers and Ni layers, CoPd alloy, FePt alloy, or a combination thereof. In one exemplary embodiment, the bottom reference layer 26 is a multi-layer film, including a CoFeB layer and a cobalt layer, wherein the CoFeB layer and the tunneling barrier layer 22 are in direct contact, and the cobalt layer and the ruthenium layer of the middle layer 28 are in direct contact. The top reference layer 30 includes a cobalt layer, and this cobalt layer and ruthenium layer of the middle reference layer 28 are in direct contact.

In the disclosure, the top reference layer 30 and the bottom reference layer 26 are of an anti-parallel magnetization arrangement, and the magnetization of the top reference layer 30 is greater than the magnetization of the bottom reference layer 26 to offset the asymmetrical reversal characteristics of the free layer 20 due to the effects of the magnetic field leakage from the bottom reference layer 26. In one exemplary embodiment, the magnetization of the top reference layer 30 is greater than the magnetization of the bottom reference layer 26 by at least 50%. In order for the magnetization of the top reference layer 30 be greater than the magnetization of the bottom reference layer 26, in one exemplary embodiment, the top reference layer 30 and the bottom reference layer 26 are formed with the same materials; however, the thickness of the top reference layer 30 is greater than the thickness of the bottom reference layer 26. In one exemplary embodiment, the magnetization of the top reference layer 30 is greater than the magnetization of the bottom reference layer 26, and the materials constituting the top reference layer 30 are the same as that constituting the bottom reference layer 26, and the number of the repeated layers of the multi-layer film in forming the top reference layer 30 are greater than the number of the repeated layers of the multi-layer film in forming the bottom reference layer 26. In another exemplary embodiment, the top reference layer 30 and the bottom reference layer 26 are formed with different materials; however, the magnetization of the top reference layer 30 is greater than the magnetization of the bottom reference layer 26 by at least 50%. For example, the top reference layer 30 includes Co/Pt multi-layer films with a greater magnetization, while the bottom reference layer 26 includes Co/Pd multi-layer films with a smaller magnetization.

The top electrode 32 is configured on the synthetic antiferromagnetic reference layer with perpendicular magnetization 24. The material of the top electrode 32 is a metal conductive material, such as Ta or TaN.

### Example 1

A CoFeB layer of 9 angstroms (hereinafter, refer to thickness) is used as a free layer. A MgO layer of 9 angstroms thick is formed on the free layer for used as a tunneling barrier layer. Thereafter, a stacked layer of [CoFeB layer of 10 angstroms/Ta layer of 2 angstroms/(Co layer of 4 angstroms/Pt layer of 15 angstroms)/two layers of (Co layer of 4 angstroms/Pt layer 5 of angstroms) (which may also be presented as (Co/Pt)×2)/Co layer of 4 angstroms] is formed as a bottom reference layer of the synthetic antiferromagnetic reference layer. Then, a Ru layer of 8 angstroms thick is formed on the bottom reference layer as the middle reference layer. Thereafter, a stacked layer of [four layers of (Co layer of 4 angstroms/Pt layer of 3 angstroms)/Co layer of 4 angstroms/Pt layer of 30 angstroms] are formed on the middle reference layer as the top reference layer of the synthetic antiferromagnetic reference layer.

### Example 2

Similar to the structure of example 1, but there is one difference between the two structures, in which the top reference layer of the synthetic antiferromagnetic reference layer in example 2 has been changed to a stacked layer of [five layers of (Co layer of 4 angstroms/Pt layer of 3 angstroms)/Co layer of 4 angstroms/Pt layer of 30 angstroms].

### Example 3

Similar to the structure of exemplary embodiment 1, but there is one difference between the two structures, in which the top reference layer of the synthetic antiferromagnetic reference layer in example 3 has been changed to a stacked layer of [six layers of (Co layer of 4 angstroms/Pt layer of 3 angstroms)/Co layer of 4 angstroms/Pt layer of 30 angstroms].

### Example 4

Similar to the structure of example 1, but there is one difference between the two structures, in which the top reference layer of the synthetic antiferromagnetic reference layer in example 4 has been changed to a stack layer of [seven layers of (Co layer 4 angstroms/Pt layer 3 angstroms)/Co layer of 4 angstroms/Pt layer of 30 angstroms].

### Example 5

A CoFeB layer of 9 angstroms thick is used as a free layer. A MgO layer of 9 angstroms thick, serving as a tunneling barrier layer, is formed on the free layer. Thereafter, a stacked layer of [CoFeB layer of 10 angstroms/Ta layer of 2 angstroms/(Co layer of 4 angstroms/Pt layer of 15 angstroms)/three layers of (Co layer of 4 angstroms/Pt layer of 5 angstroms)/Co layer of 4 angstroms] is formed as a bottom reference layer of the synthetic antiferromagnetic reference layer. A Ru layer of 8 angstroms is then formed on the bottom reference layer as the middle reference layer of the synthetic antiferromagnetic reference layer. Thereafter, a stacked layer of [four layers of (Co layer of 4 angstroms/Pt layer of 3 angstroms)/Co layer of 4 angstroms/Pt layer of 30 angstroms] is formed on the middle reference layer as the top reference layer of the synthetic antiferromagnetic reference layer.

### Example 6

Similar to the structure of example 5, but there is one difference between the two structures, in which the bottom reference layer of the synthetic antiferromagnetic reference layer in example 6 has been changed to a stacked layer of [CoFeB layer of 10 angstroms/Ta layer of 2 angstroms/(Co layer of 4 angstroms/Pt layer of 15 angstroms)/two layers of (Co layer of 4 angstroms/Pt layer of 5 angstroms)/Co layer of 4 angstroms].

### Example 7

Similar to the structure of example 5, but there is one difference between the two structures, in which the bottom reference layer of the synthetic antiferromagnetic reference layer in example 6 has been changed to a stacked layer of [CoFeB layer of 10 angstroms/Ta layer of 2 angstroms/(Co layer of 4 angstroms/Pt layer of 15 angstroms)/(Co layer of 4 angstroms/Pt layer of 5 angstroms)/Co layer of 4 angstroms].

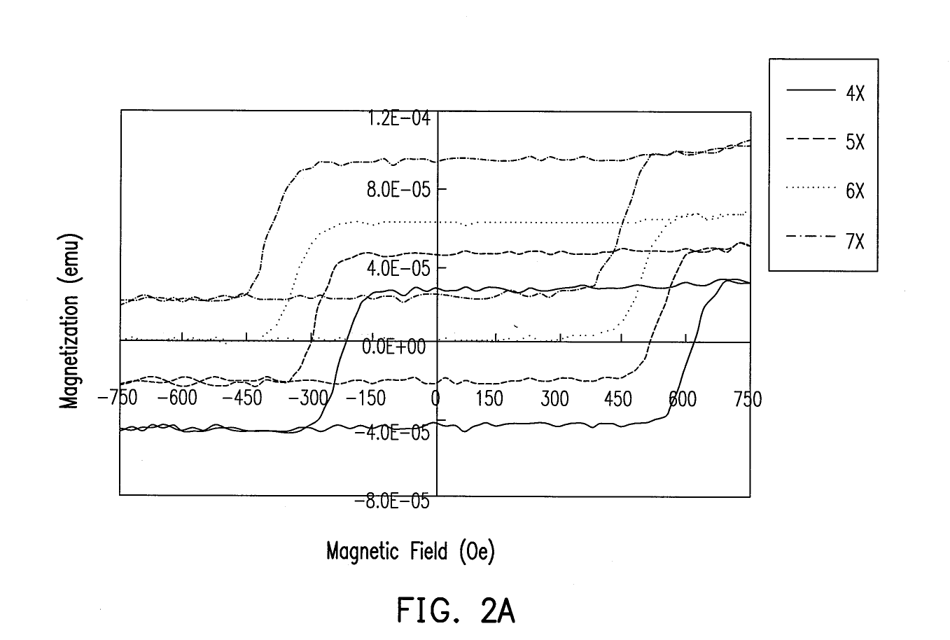

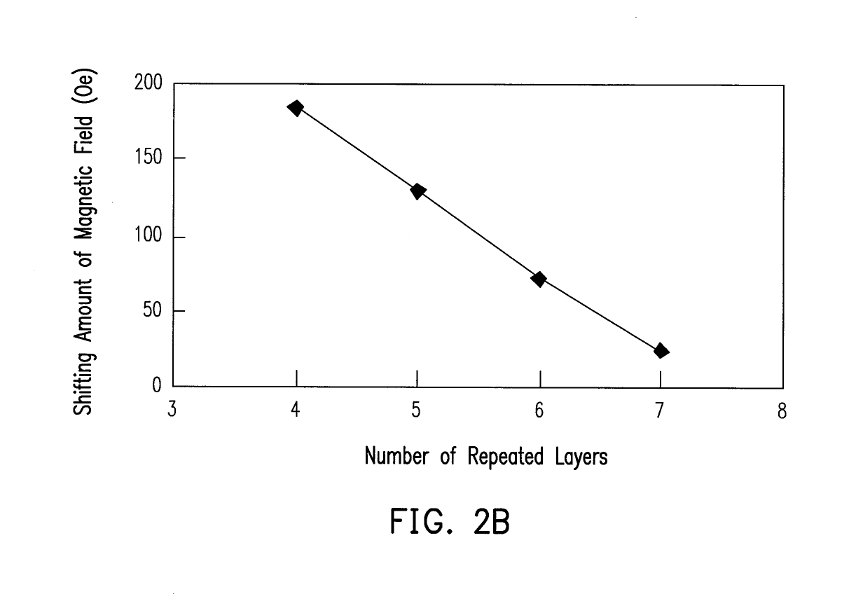

FIG. 2A illustrates the hysteresis loops of the free layer switching in Examples 1 to 4. The relationship between the number of the repeated layers (Co layer of 4 angstroms/Pt layer of 3 angstroms) in the top reference layer and the shifting amount of the magnetic field in the free layer is illustrated in FIG. 2B. The results indicate that the shifting amount decreases as the number of the repeated layers (Co layer of 4 angstroms/Pt layer of 3 angstroms) in the top reference layer increases.

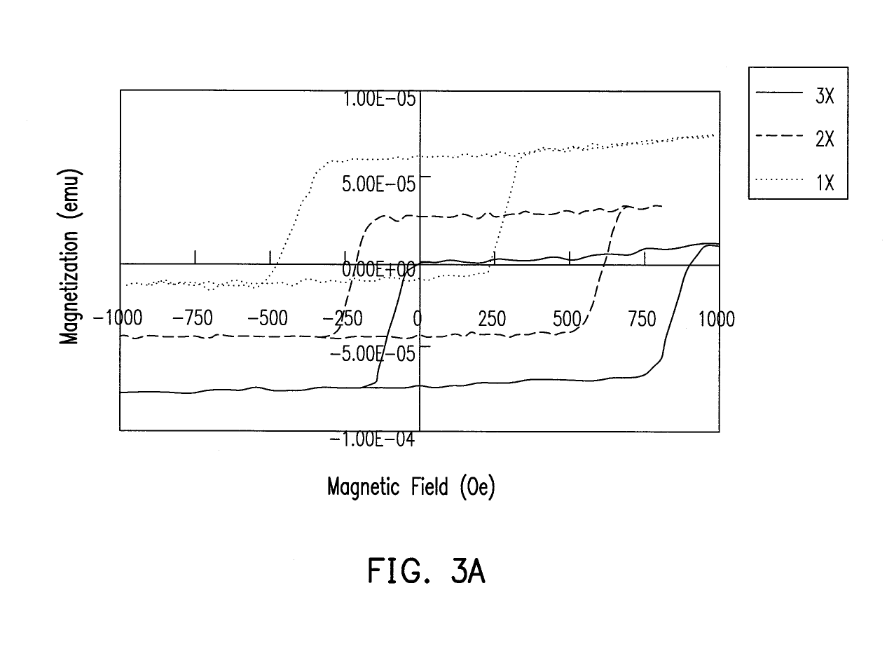

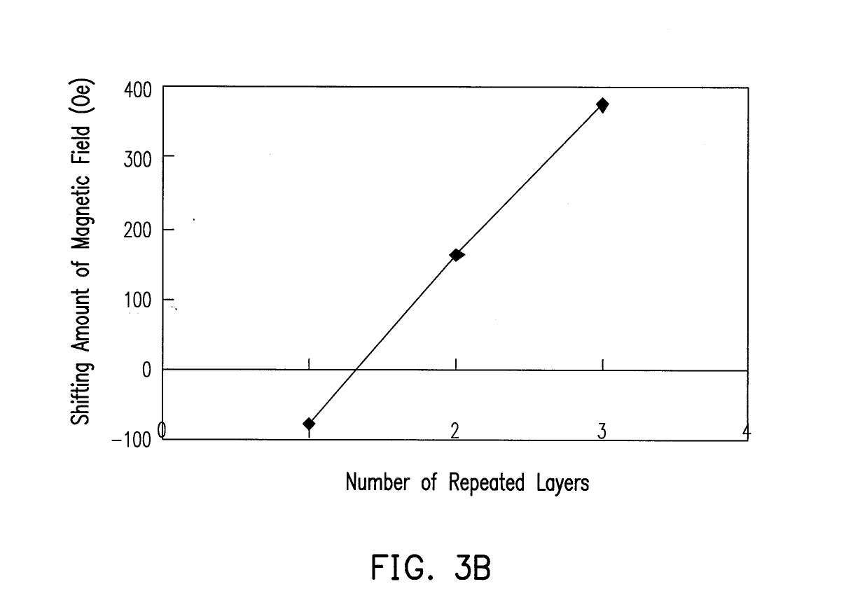

FIG. 3A illustrates the hysteresis loops of the magnetization reversal of the free layer in Examples 5 to 7. The relationship between the number of the repeated layers (Co layer of 4 angstroms/Pt layer of 5 angstroms) in the bottom reference layer and the shifting amount of the magnetic field in the free layer is illustrated in FIG. 3B. The results indicate that the shifting amount decreases as the number of the repeated layers (Co layer of 4 angstroms/Pt layer of 5 angstroms) in the bottom reference layer decreases. These results indicate that the greater difference in the number of the repeated layers between the bottom reference layer and the top reference layer, the better the offset of the asymmetrical reversal characteristic of the free layer due to the effects of the magnetic field leakage from the bottom reference layer.

According to the above disclosure, the magnetic tunnel junction device with perpendicular magnetization is a top-pinned structure. In essence, the free layer is configured under the tunneling barrier layer while the synthetic antiferromagnetic reference layer is positioned above the tunneling barrier layer, and all the magnetic layers are magnetized perpendicular to the film surface. The bottom electrode and the free layer of the exemplary embodiments of the disclosure further include an addition of a layer or a multi-layer of non-ferromagnetic layers as a spacer therebetween to increase the distance between the free layer and the bottom electrode layer. The spacer serves to prevent the redeposit of the bottom electrode materials to the top and the bottom of the tunneling barrier layer and the formation of a short-circuit path after the etching of the device. Moreover, the magnetization of the synthetic antiferromagnetic top reference layer is greater than the magnetization of the synthetic antiferromagnetic bottom reference layer to offset the asymmetrical reversal of the free layer due to effects of the magnetic field leakage from the bottom reference layer.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A top-pinned magnetic tunnel junction device with perpendicular magnetization, comprising:
a bottom electrode;
a non-ferromagnetic spacer, configured on the bottom electrode;
a free layer, located on the non-ferromagnetic spacer;
a tunneling barrier layer, configured on the free layer;
a synthetic antiferromagnetic reference layer, positioned on the tunneling barrier layer, and the synthetic antiferromagnetic reference layer comprising:
a bottom reference layer, configured on the tunneling barrier layer;
a middle reference layer, positioned on the bottom reference and the middle reference layer is a ruthenium layer; and
a top reference layer, configured on the middle reference layer, wherein a magnetization of the top reference layer is greater than a magnetization of the bottom reference layer; and
a top electrode, configured on the synthetic antiferromagnetic reference layer.

2. The top-pinned magnetic tunnel junction device with perpendicular magnetization of claim 1, wherein the top reference layer and the bottom reference are of an anti-parallel magnetization arrangement.

3. The top-pinned magnetic tunnel junction device with perpendicular magnetization of claim 1, wherein the magnetization of the top reference layer is greater than the magnetization of the bottom reference layer by at least 50%.

4. The top-pinned magnetic tunnel junction device with perpendicular magnetization of claim 3, wherein the top reference layer and the bottom reference layer are constituted with the same materials, and a thickness of the top reference layer is greater than a thickness of the bottom reference layer.

5. The top-pinned magnetic tunnel junction device with perpendicular magnetization of claim 3, wherein the top reference layer and the bottom reference layer respectively comprise a multi-layer film, and the multi-layer film of the top reference layer and the multi-layer film of the bottom reference layer are constituted with the same materials, and a number of layers of the multi-layer film of the top reference layer is greater than a number of layers of the multi-layer film of the bottom reference layer.

6. The top-pinned magnetic tunnel junction device with perpendicular magnetization of claim 3, wherein the top reference layer and the bottom reference layer are constituted with different materials.

7. The top-pinned magnetic tunnel junction device with perpendicular magnetization of claim 1, wherein the non-ferromagnetic spacer comprises an amorphous material or a material with a grain size smaller than 100 nm.

8. The top-pinned magnetic tunnel junction device with perpendicular magnetization of claim 1, wherein the top reference layer and the bottom reference layer respectively include a perpendicular magnetic anisotropy material that comprises a CoFeB (cobalt iron boron) single layer film, a multi-layer film formed with Co (cobalt) layers and Pt (platinum) layers, a multi-layer film formed with Co (cobalt) layers and Pd (palladium) layers, a multi-layer film formed with Co layers and Ni (nickel) layers, a CoPd (cobalt palladium) alloy, a FePt (iron platinum) alloy, or a combination thereof.

9. The top-pinned magnetic tunnel junction device with perpendicular magnetization of claim 1, wherein the top reference layer and the bottom reference layer respectively include a cobalt layer, and are respectively in direct contact with the ruthenium layer of the middle reference layer.

10. The top-pinned magnetic tunnel junction device with perpendicular magnetization of claim 1, wherein the top reference layer and the free layer respectively include a CoFeB layer and are respectively in direct contact with the tunneling barrier layer.

11. The top-pinned magnetic tunnel junction device with perpendicular magnetization of claim 1, wherein the free layer is constituted with a perpendicular magnetic anisotropy material that comprises a CoFeB single layer film, a multi-layer film formed with Co layers and Pt layers, a multi-layer film formed with Co layers and Pd layers, a multi-layer film formed with Co layers and Ni layers, a CoPd alloy, a FePt alloy, or a combination thereof.

12. The top-pinned magnetic tunnel junction device with perpendicular magnetization of claim 1, wherein the tunneling barrier layer comprises aluminum oxide or magnesium oxide.

13. A top-pinned magnetic tunnel junction device with perpendicular magnetization, comprising:
a bottom electrode;
a non-ferromagnetic spacer, configured on the bottom electrode, the non-ferromagnetic spacer comprising:
a first spacer, positioned on the bottom electrode; and
a second spacer, positioned on the first spacer;
a free layer, located on the non-ferromagnetic spacer;
a tunneling barrier layer, configured on the free layer;
a synthetic antiferromagnetic reference layer, positioned on the tunneling barrier layer; and
a top electrode, configured on the synthetic antiferromagnetic reference layer.

14. The top-pinned magnetic tunnel junction device with perpendicular magnetization of claim 13, wherein the first spacer comprises an amorphous material or a material with a grain size smaller than 100 nm, and the second spacer comprises a non-ferromagnetic material comprising tantalum or ruthenium.

15. The top-pinned magnetic tunnel junction device with perpendicular magnetization of claim 13, wherein the synthetic antiferromagnetic reference layer comprises:
a bottom reference layer, configured on the tunneling barrier layer;
a middle reference layer, positioned on the bottom reference and the middle reference layer is a ruthenium layer; and
a top reference layer, configured on the middle reference layer, wherein a magnetization of the top reference layer is greater than a magnetization of the bottom reference layer, and the top reference layer and the bottom reference layer respectively include a perpendicular magnetic anisotropy material that comprises a CoFeB single layer film, a multi-layer film formed with Co layers and Pt layers, a multi-layer film formed with Co layers and Pd layers, a multi-layer film formed with Co layers and Ni layers, a CoPd alloy, a FePt alloy, or a combination thereof.

16. The top-pinned magnetic tunnel junction device with perpendicular magnetization of claim 13, wherein the free layer is formed with a perpendicular magnetic anisotropy material that comprises a CoFeB single layer film, a multi-layer film formed with Co layers and Pt layers, a multi-layer film formed with Co layers and Pd layers, a multi-layer film formed with Co layers and Ni layers, a CoPd alloy, a FePt alloy, or a combination thereof.

17. The top-pinned magnetic tunnel junction device with perpendicular magnetization of claim 13, wherein the tunneling insulation layer comprises aluminum oxide or magnesium oxide.

18. A top-pinned magnetic tunnel junction device with perpendicular magnetization, comprising:
a bottom electrode;
a non-ferromagnetic spacer, configured on the bottom electrode, the non-ferromagnetic spacer comprising:
a first spacer, positioned on the bottom electrode; and
a second spacer, positioned on the first spacer;
a free layer, located on the non-ferromagnetic spacer;
a tunneling barrier layer, configured on the free layer;
a synthetic antiferromagnetic reference layer, positioned on the tunneling barrier layer, and the synthetic antiferromagnetic reference layer comprising:
a bottom reference layer, configured on the tunneling barrier layer;
a middle reference layer, positioned on the bottom reference and the middle reference layer is a ruthenium layer; and
a top reference layer, configured on the middle reference layer, wherein a magnetization of the top reference layer is greater than a magnetization of the bottom reference layer; and
a top electrode, configured on the synthetic antiferromagnetic reference layer.

19. The top-pinned magnetic tunnel junction device with perpendicular magnetization of claim 18, wherein the top reference layer and the bottom reference are of an anti-parallel magnetization arrangement.

20. The top-pinned magnetic tunnel junction device with perpendicular magnetization of claim 18, wherein the magnetization of the top reference layer is greater than the magnetization of the bottom reference layer by at least 50%.

21. The top-pinned magnetic tunnel junction device with perpendicular magnetization of claim 18, wherein the top reference layer and the bottom reference layer are constituted with the same material, and a thickness of the top reference layer is greater than a thickness of the bottom reference layer.

22. The top-pinned magnetic tunnel junction device with perpendicular magnetization of claim 18, wherein the top reference layer and the bottom reference layer respectively comprise a multi-layer film, and the multi-layer film of the top reference layer and the multi-layer film of the bottom reference layer are constituted with the same materials, and a number of layers of the multi-layer film of the top reference layer is greater than a number of layers of the multi-layer film of the bottom reference layer.

23. The top-pinned magnetic tunnel junction device with perpendicular magnetization of claim 18, wherein the top reference layer and the bottom reference layer are constituted with different materials.

24. The top-pinned magnetic tunnel junction device with perpendicular magnetization of claim 18, wherein the first spacer comprises an amorphous material or a material with a grain size smaller than 100 nm, while the second spacer comprises a non-ferromagnetic material including tantalum or ruthenium.

25. The top-pinned magnetic tunnel junction device with perpendicular magnetization of claim 18, wherein the top reference layer and the bottom reference layer respectively include a cobalt layer, and are respectively in direct contact with the ruthenium layer of the middle reference layer.

26. The top-pinned magnetic tunnel junction device with perpendicular magnetization of claim 18, wherein the top reference layer and the free layer respectively include a CoFeB layer and are respectively in direct contact with the tunneling barrier layer.

27. The top-pinned magnetic tunnel junction device with perpendicular magnetization of claim 18, wherein the free layer is constituted with a perpendicular magnetic anisotropy material that includes a CoFeB single layer film, a multi-layer film formed with Co layers and Pt layers, a multi-layer film formed with Co layers and Pd layers, a multi-layer film formed with Co layers and Ni layers, a CoPd alloy, a FePt alloy, or a combination thereof.

28. The top-pinned magnetic tunnel junction device with perpendicular magnetization of claim 18, wherein the bottom reference layer and the top reference layer are respectively constituted with a perpendicular magnetic anisotropy material that includes a CoFeB single layer film, a multi-layer film formed with Co layers and Pt layers, a multi-layer film formed with Co layers and Pd layers, a multi-layer film formed with Co layers and Ni layers, a CoPd alloy, a FePt alloy, or a combination thereof.

29. The top-pinned magnetic tunnel junction device with perpendicular magnetization of claim 18, wherein the tunneling barrier layer comprises aluminum oxide or magnesium oxide.
